(19) United States
(12) Patent Application Publication
(10) Pub. No.: US 2025/0239521 A1
(43) Pub. Date: Jul. 24, 2025

(54) STACKED FIELD EFFECT TRANSISTOR WITH EPITAXY CUT FOR SOURCE/DRAIN CONTACT

(71) Applicant: International Business Machines Corporation, Armonk, NY (US)

(72) Inventors: Shay Reboh, Guilderland, NY (US); Debarghya Sarkar, Latham, NY (US); Ruilong Xie, Niskayuna, NY (US); Lijuan Zou, Albany, NY (US); Jay William Strane, Wappingers Falls, NY (US)

(21) Appl. No.: 18/416,115

(22) Filed: Jan. 18, 2024

(51) Int. Cl. H01L 23/528; H01L 21/822; H01L 21/8238; H01L 27/092; H01L 29/06; H01L 29/417; H01L 29/423; H01L 29/66; H01L 29/775; H01L 29/786

(52) U.S. Cl. CPC H01L 23/5286; H10D 30/014; H10D 30/43; H10D 30/6729; H10D 30/6735; H10D 30/6757; H10D 62/121; H10D 84/0186; H10D 84/038; H10D 84/856; H10D 88/01

(57) ABSTRACT

A semiconductor device is provided. The semiconductor device includes a back-end-of-line (BEOL) layer, a backside power distribution network (BSPDN), a stacked field effect transistor (stacked FET) and a backside contact. The stacked FET is vertically interposed between the BEOL layer and the BSPDN and includes a top FET with top source/drain (S/D) epitaxy and a bottom FET with bottom S/D epitaxy. The stacked FET is characterized as having at least partial vertical alignment of the top FET and the bottom FET. A backside contact electrically connects the BSPDN and the top S/D epitaxy and cuts through the bottom S/D epitaxy with isolation between the backside contact and the bottom S/D epitaxy.

### BACKGROUND

The present disclosure generally relates to fabrication methods and resulting structures for semiconductor devices. More specifically, the present disclosure relates to a semiconductor device structure a field effect transistor (FET) with an epitaxy that is cut for source/drain (S/D) contact.

A transistor is a semiconductor device used to amplify or switch electrical signals and power and is one of the basic building blocks of modern electronics. A field-effect transistor (FET) is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a semiconductor device is provided and includes a back-end-of-line (BEOL) layer, a backside power distribution network (BSPDN), a stacked field effect transistor (stacked FET) and a backside contact. The stacked FET is vertically interposed between the BEOL layer and the BSPDN and includes a top FET with top source/drain (S/D) epitaxy and a bottom FET with bottom S/D epitaxy. The stacked FET is characterized as having at least partial vertical alignment of the top FET and the bottom FET. A backside contact electrically connects the BSPDN and the top S/D epitaxy and cuts through the bottom S/D epitaxy with isolation between the backside contact and the bottom S/D epitaxy.

According to an aspect of the disclosure, a semiconductor device is provided and includes a back-end-of-line (BEOL) layer, a backside power distribution network (BSPDN), a stacked field effect transistor (stacked FET), a backside contact and a frontside contact. The stacked FET is vertically interposed between the BEOL layer and the BSPDN and includes a top FET with top source/drain (S/D) epitaxy and a bottom FET with bottom S/D epitaxy. The stacked FET is characterized as having at least partial vertical alignment of the top FET and the bottom FET and with the top FET and the bottom FET having different channel widths. The backside contact electrically connects the BSPDN and the top S/D epitaxy and cuts through the bottom S/D epitaxy with isolation between the backside contact and the bottom S/D epitaxy. The frontside contact electrically connects the BEOL layer and the bottom S/D epitaxy and is displaced from the top S/D epitaxy.

According to an aspect of the disclosure, a semiconductor device fabrication method is provided. The semiconductor device fabrication method includes forming a stacked field effect transistor (stacked FET) including a top FET with top source/drain (S/D) epitaxy and a bottom FET with bottom S/D epitaxy and being characterized as having at least partial vertical alignment of the top FET and the bottom FET. The semiconductor device fabrication method further includes cutting a frontside opening through the top S/D epitaxy to the bottom S/D epitaxy, lining the frontside opening with a frontside dielectric liner, forming, in a frontside opening remainder, a frontside contact cutting through the top S/D epitaxy with frontside dielectric liner isolation to the bottom S/D epitaxy, cutting a backside opening through the bottom S/D epitaxy to the top S/D epitaxy, lining the backside opening with a backside dielectric liner and forming, in a backside opening remainder, a backside contact cutting through the bottom S/D epitaxy with backside dielectric liner isolation to the top S/D epitaxy.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a top-down view of a semiconductor device in accordance with one or more embodiments;

FIG. 2 is a side view of the semiconductor device of FIG. 1 with frontside and backside contacts taken along lines Y1 and Y2 of FIG. 1 in accordance with one or more embodiments;

FIG. 3 is a side view of the semiconductor device of FIG. 1 with frontside and backside contacts disposed in contact with multiple sides of S/D epitaxy taken along lines Y1 and Y2 of FIG. 1 in accordance with one or more embodiments;

FIG. 4 is a side view of the semiconductor device of FIG. 1 with top and bottom FETs having different channel widths taken along lines Y1 and Y2 of FIG. 1 in accordance with one or more embodiments;

FIG. 5 is a flow diagram illustrating a semiconductor device fabrication method in accordance with one or more embodiments;

FIG. 6 is a side view of a semiconductor device assembly in a first stage of assembly in accordance with one or more embodiments;

FIG. 7 is a side view of a semiconductor device assembly in a second stage of assembly in accordance with one or more embodiments;

FIG. 8 is a side view of a semiconductor device assembly in a third stage of assembly in accordance with one or more embodiments;

FIG. 9 is a side view of a semiconductor device assembly in a fourth stage of assembly in accordance with one or more embodiments; and

FIG. 10 is a side view of a semiconductor device assembly that generally corresponds to the semiconductor device of FIG. 2 in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, a stacked FET is an FET in which bottom and top FETs are stacked in a vertical direction, with one on top of another. In devices that include stacked FETs, there can be a need for connectivity of the stacked FETs with a backside power distribution network (BSPDN) and aligned top and bottom S/D regions. Such connectivity often requires that contacts from a back-side and a front-side of the semiconductor device circumvent the bottom and the top FETs in order to reach the respectively opposed FETs. For example, a front side signal has to circumvent the top epitaxy of the top FET in a stacked FET in order to reach the bottom FET.

Accordingly, there remains a need for an improved semiconductor device structure in which connectivity of the stacked FETs with a BSPDN and aligned top and bottom S/D regions does not require contacts that circumvent the bottom and the top FETs in order to reach the respectively opposed FETs.

Turning now to an overview of the aspects of the disclosure, one or more embodiments of the disclosure address the above-described shortcomings of the prior art by providing a semiconductor device in which contacts are formed to cut through an overburden region of S/D regions to reach the opposed FET. This allows for a reduction in a via aspect ratio of the semiconductor device as well as a scaling of the cell height (as used herein, “cell height” is measured in a width-wise direction). The contacts are isolated from the S/D regions being avoided through dielectric liners.

The above-described aspects of the disclosure address the shortcomings of the prior art by providing for semiconductor device that includes a back-end-of-line (BEOL) layer, a BSPDN, a stacked FET and a backside contact. The stacked FET is vertically interposed between the BEOL layer and the BSPDN and includes a top FET with top S/D epitaxy and a bottom FET with bottom S/D epitaxy and is characterized as having at least partial vertical alignment of the top FET and the bottom FET. The backside contact electrically connects the BSPDN and the top S/D epitaxy and cuts through the bottom S/D epitaxy with isolation between the backside contact and the bottom S/D epitaxy.

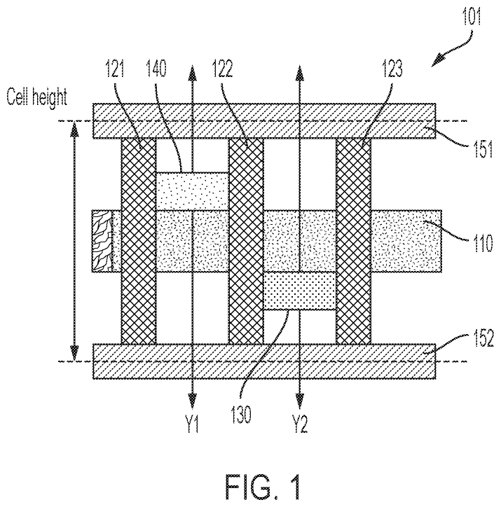

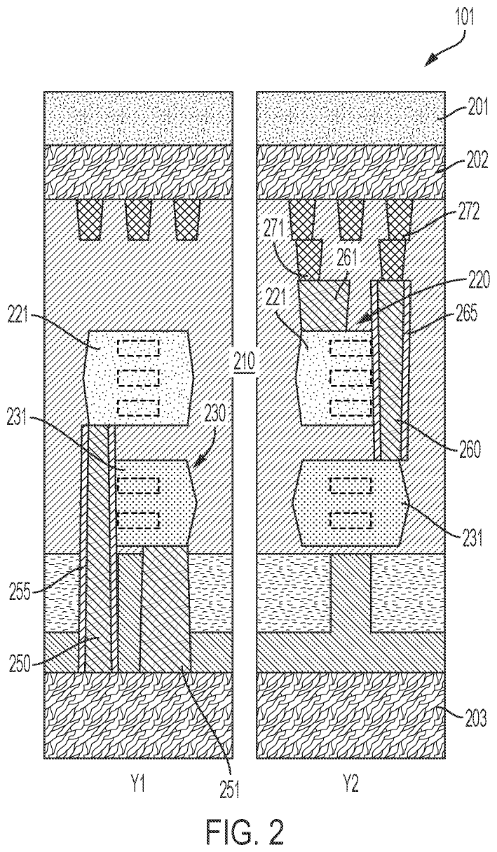

Turning now to a more detailed description of aspects of the present disclosure, FIG. 1 depicts a top-down view of a semiconductor device 101. FIGS. 2-4 are side views of the semiconductor device 101 in accordance with embodiments. FIGS. 2-4 are each taken from a perspective defined by cross-sectional views Y1 and Y2 of FIG. 1.

As shown in FIG. 1, the semiconductor device 101 includes an active region 110, gates 121, 122, 123 that cross the active region 110, a frontside contact 130 and a backside contact 140. The semiconductor device 101 further includes cell boundaries 151, 152 on opposite sides of the active region 110 and the gates 121, 122, 123 and a cell height that is measured between the cell boundaries 151, 152. The cell height is a reduced cell height owing at least partially to the configurations of the frontside contact 130 and the backside contact 140.

As shown in FIG. 2, the semiconductor device 101 includes a wafer layer 201, a BEOL layer 202, and BSPDN 203 and a stacked FET 210. The stacked FET 210 is vertically interposed between the BEOL layer 202 and the BSPDN 203. The stacked FET 210 includes a top FET 220 with top S/D epitaxy 221 and a bottom FET 230 with bottom S/D epitaxy 231. The stacked FET 210 is characterized as having at least partial vertical alignment of the top FET 220 and the bottom FET 230 with the top FET 220 and the bottom FET 230 having same channel widths.

The semiconductor device 101 further includes at least one or both of a backside contact 250 (i.e., the backside contact 140 of FIG. 1) and a frontside contact 260 (i.e., the frontside contact 130 of FIG. 1). For purposes of clarity and brevity, unless stated otherwise, the following description will relate to the case in which the semiconductor device 101 includes both the backside contact 250 and the frontside contact 260. The backside contact 250 electrically connects the BSPDN 203 and the top S/D epitaxy 221. The backside contact 250 also cuts through the bottom S/D epitaxy 231 with there being electrical isolation between the backside contact 250 and the bottom S/D epitaxy 231. A backside dielectric liner 255 is disposed to provide for the electrical isolation of the backside contact 250 from the bottom S/D epitaxy 231. The frontside contact 260 electrically connects the BEOL layer 202 and the bottom S/D epitaxy 231. The frontside contact 260 also cuts through the top S/D epitaxy 221 with there being electrical isolation between the frontside contact 260 and the top S/D epitaxy 221. A frontside dielectric liner 265 is disposed to provide for the electrical isolation of the frontside contact 260 from the top S/D epitaxy 221.

In addition, the semiconductor device 101 includes an additional backside contact 251, an additional frontside contact 261 and one or more metallization layers 271, 272. The additional backside contact 251 electrically connects the BSPDN 203 and the bottom S/D epitaxy 231. The additional frontside contact 261 electrically connects the BEOL layer 202 and the top S/D epitaxy 221. The one or more metallization layers 271, 272 are electrically interposed between the BEOL layer 202 and the frontside contact 260 and between the BEOL layer 202 and the additional frontside contact 261.

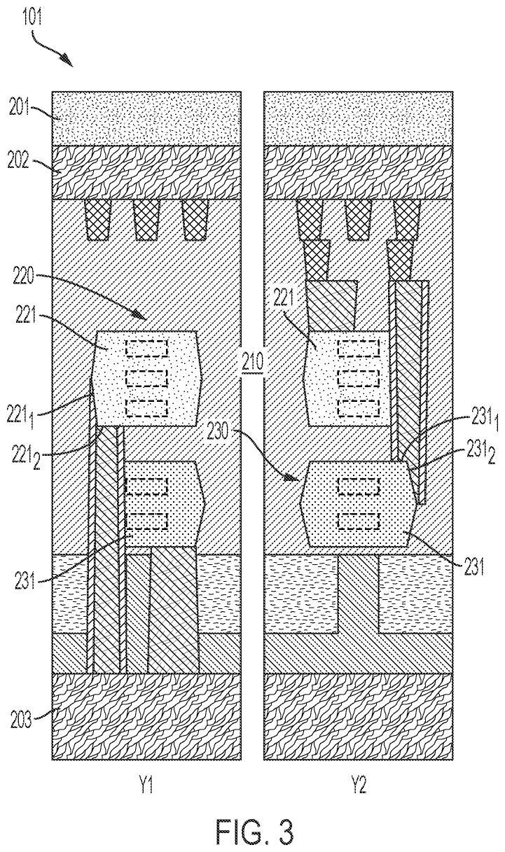

As shown in FIG. 3 and in accordance with embodiments, the backside contact 250 can be disposed in contact with multiple sides 2211, 2212 of the top S/D epitaxy 221 and the frontside contact 260 can be disposed in contact with multiple sides 2311, 2312 of the bottom S/D epitaxy 231.

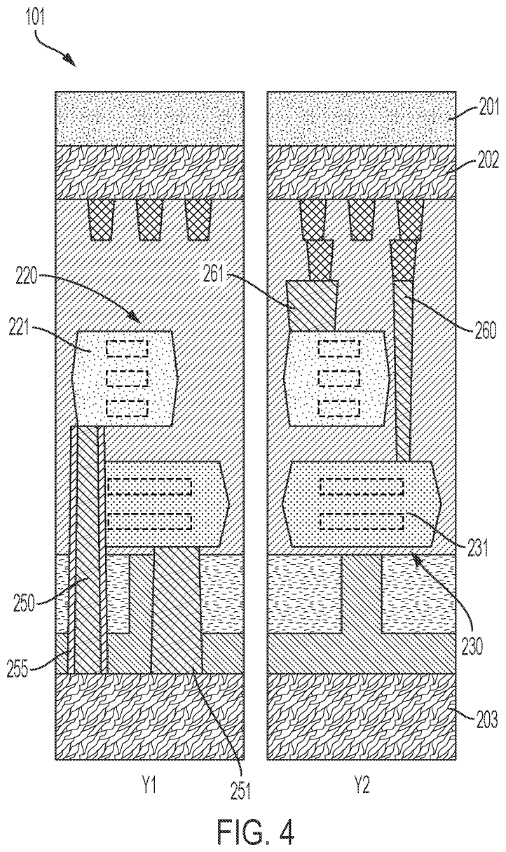

As shown in FIG. 4, the semiconductor device 101 is provided in a similar manner as described above except that the stacked FET 210 is characterized in that the top FET 220 and the bottom FET 230 have different channel widths, respectively. In these or other cases, while the backside contact 250 cuts through the bottom S/D epitaxy 231 as described above, the frontside contact 260 electrically connects the BEOL layer 202 and the bottom S/D epitaxy 231 and is displaced from the top S/D epitaxy 221 and so does not need to cut through the top S/D epitaxy 221.

It is to be understood that the various embodiments of FIGS. 2-4 are interchangeable with one another. For example, in the embodiments of FIG. 4, the frontside contact 260 could cut through the top S/D epitaxy 221 and the backside contact 250 could be displaced from the bottom S/D epitaxy 231 and thus not need to cut through the bottom S/D epitaxy 231. In addition, the embodiments of FIGS. 3 and 4 can be combined. That is, at least one of the backside contact 250 could be disposed in contact with multiple sides of the top S/D epitaxy 221 and the frontside contact 260 could be disposed in contact with multiple sides of the bottom S/D epitaxy 231.

In any case, to the extent that top or bottom S/D epitaxy is removed to make room for the backside or frontside contacts as described above, the contacts that are made between the backside and frontside contacts with the top and bottom S/D epitaxy are sufficient. Meanwhile, the corresponding reduction in cell height owing to the effective inward shift of the backside and frontside contacts provides for an advantageous configuration with a reduced size for scaling purposes.

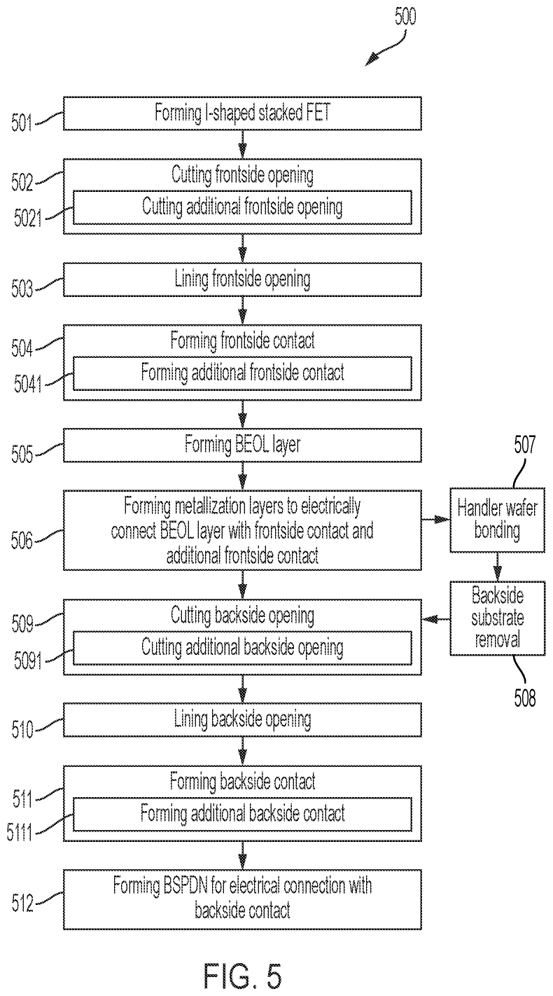

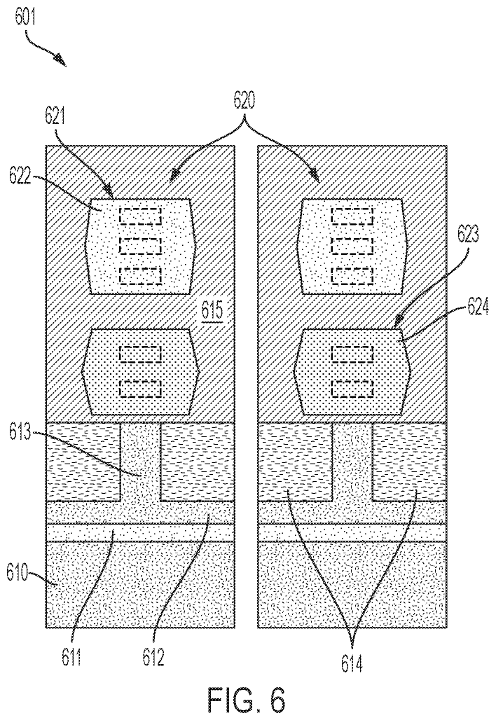

With reference to FIG. 5 and with additional reference to FIGS. 6-10, a semiconductor device fabrication method 500 is provided to form the semiconductor device 101 of FIG. 1 and FIGS. 2-4. FIGS. 6-10 are each taken from a perspective defined by cross-sectional views Y1 and Y2 of FIG. 1.

As shown in FIG. 5, the semiconductor device fabrication method 500 includes forming a stacked FET as described above (block 501) and at least one or both of frontside contact formation (blocks 502, 503, 504) and backside contact formation (blocks 509, 510, 511). As above, for purposes of clarity and brevity, the following description will relate to the case of the semiconductor device fabrication method 500 including both frontside and backside contact formations.

The frontside contact formation of the semiconductor device fabrication method 500 includes cutting a frontside opening through top S/D epitaxy to bottom S/D epitaxy (block 502), lining the frontside opening with a frontside dielectric liner (block 503) and forming, in a remainder of the frontside opening, a frontside contact cutting to the bottom S/D epitaxy through the top S/D epitaxy with frontside dielectric liner isolation provided by the frontside dielectric liner (block 504).

In addition, the semiconductor device fabrication method 500 can include forming a BEOL layer for electrical connection with the frontside contact (block 505) and forming one or more metallization layers between the frontside contact and the BEOL layer (block 506). Subsequently, a handler wafer bonding (block 507) operation and a backside substrate removal (block 508) are executed.

The backside contact formation of the semiconductor device fabrication method 500 includes cutting a backside opening through the bottom S/D epitaxy to the top S/D epitaxy (block 509), lining the backside opening with a backside dielectric liner (block 510) and forming, in a remainder of the backside opening, a backside contact cutting to the top S/D epitaxy through the bottom S/D epitaxy with backside dielectric liner isolation provided by the backside dielectric liner (block 511).

In accordance with embodiments, the cutting of the frontside opening of block 502 and the forming of the frontside contact of block 504 can be executed such that the frontside contact is disposed in contact with multiple sides of the bottom S/D epitaxy and the cutting of the backside opening of block 509 and the forming of the backside contact of block 511 can be executed such that the backside contact is disposed in contact with multiple sides of the top S/D epitaxy.

In addition, the semiconductor device fabrication method 500 can include forming a BSPDN for electrical connection with the backside contact (block 510).

The semiconductor device fabrication method 500 can also include cutting an additional frontside opening to the top S/D epitaxy (block 5021) and forming, in the additional frontside opening, an additional frontside contact to the top S/D epitaxy (block 5041) as well as cutting an additional backside opening to the bottom S/D epitaxy (block 5091), optionally lining the additional backside opening with dielectric liner and forming, in the additional backside opening (i.e., in the remainder of the additional backside opening where the additional backside opening has been lined), an additional backside contact to the bottom S/D epitaxy (block 5111). In these or other cases, the backside dielectric liner of the backside contact and the additional backside dielectric liner of the additional backside contact can be formed to be adjacent.

As shown in FIG. 6, a semiconductor device assembly 601 is provided in an initial stage of assembly following front-end-of-line (FEOL) fabrication and includes a semiconductor substrate 610 that can be formed of a semiconductor material, such as silicon, an etch stop layer 611 that can be formed of a different semiconductor material, such as silicon-germanium, and an upper substrate layer 612, which can be formed of the semiconductor material of the semiconductor substrate 610, and which is formed to include a pedestal 613 extending upwardly. The semiconductor device assembly 601 further includes shallow trench isolation (STI) 614 surrounding the pedestal 613, dielectric material 615 disposed on the pedestal 613 and the STI 614 and a stacked FET 620 suspended within the dielectric material 615. The stacked FET 620 includes a top FET 621 with top S/D epitaxy 622 and a bottom FET 623 with bottom S/D epitaxy 624. In accordance with embodiments, as described above, the top FET 621 and the bottom FET 623 can have same or different channel widths. For purposes of clarity and brevity, the following description will relate to the case in which the top FET 621 and the bottom FET 623 have same channel widths.

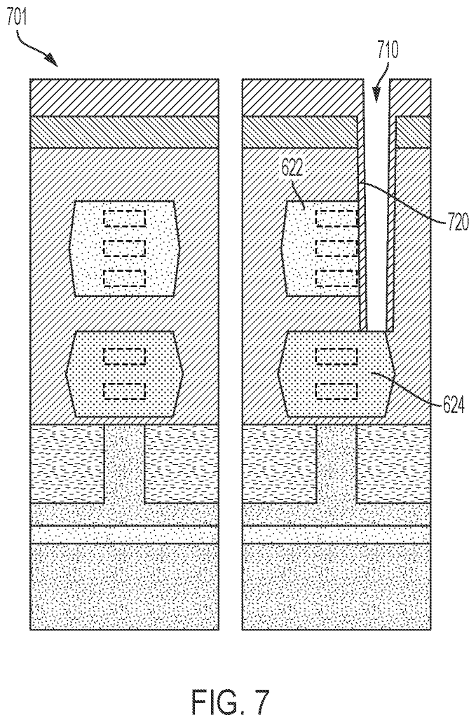

As shown in FIG. 7, a semiconductor device assembly 701 is provided in a second stage of assembly following a frontside opening 710 being formed through the top S/D epitaxy 622 to the bottom S/D epitaxy 624 and inner spacer deposition and etching to form a frontside dielectric liner 720 lining the frontside opening 710 applied with respect to the semiconductor device assembly 601 of FIG. 6.

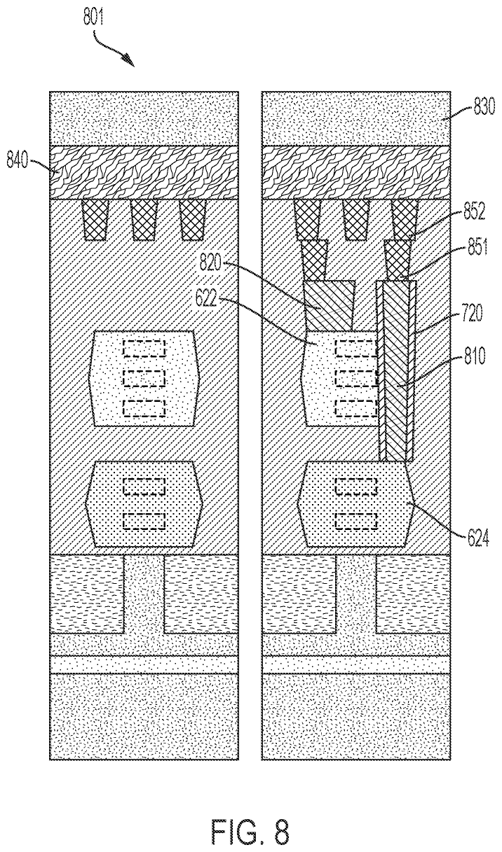

As shown in FIG. 8, a semiconductor device assembly 801 is provided in a third stage of assembly following frontside contact metallization and frontside interconnect formations applied with respect to the semiconductor device assembly 701 of FIG. 7. The frontside contact metallization results in the formation of a frontside contact 810 in the remainder of the frontside opening 710 of FIG. 7. The frontside contact 810 extends through the top S/D epitaxy 622 to the bottom S/D epitaxy 624 and is electrically isolated from the top S/D epitaxy 622 by the frontside dielectric liner 720. The semiconductor device assembly 801 can further include an additional frontside contact 820 that extends to the top S/D epitaxy 622. The frontside interconnect formations result in the formation of carrier wafer layer 830, BEOL layer 840 and metallization layers 851, 852 by which the frontside contact 810 and the additional frontside contact 820 are electrically connected to the BEOL layer 840.

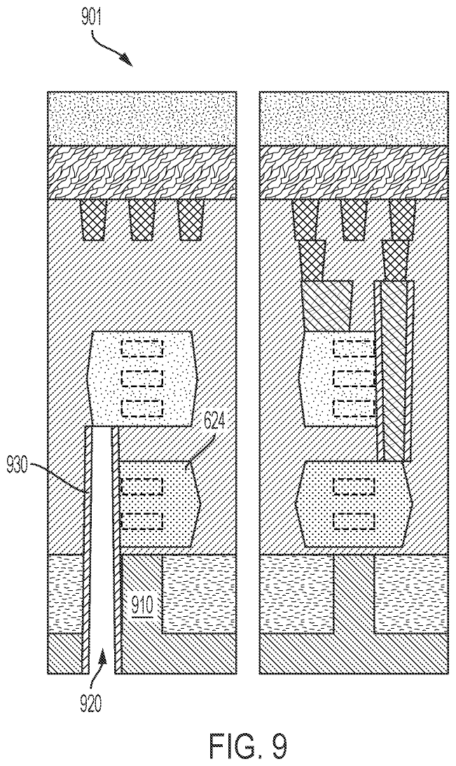

As shown in FIG. 9, a semiconductor device assembly 901 is provided in a fourth stage of assembly following wafer flip, substrate removal and backside interlayer dielectric (ILD) deposition applied with respect to the semiconductor device assembly 801 of FIG. 8. The ILD deposition results in the formation of ILD 910 where the upper substrate layer 612 of FIG. 6 was previously. The semiconductor device assembly 901 is further formed as a result of a backside opening 920 being formed through the ILD 910 and the bottom S/D epitaxy 624 to the top S/D epitaxy 622 and formation of a backside dielectric liner 930 that is disposed to line the backside opening 920.

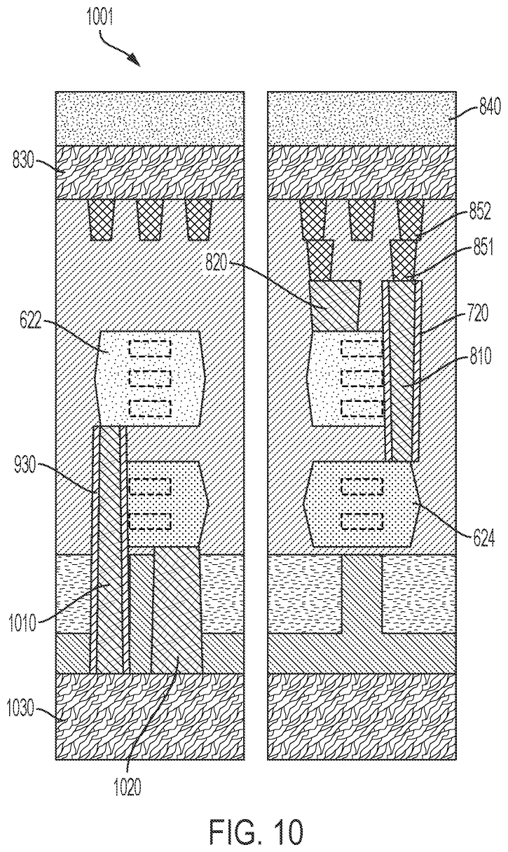

As shown in FIG. 10, a semiconductor device assembly 1001 is provided and generally corresponds to the semiconductor device 101 of FIG. 2 following formation of an additional backside opening, backside contact metallization and backside interconnect formation applied with respect to the semiconductor device assembly 901 of FIG. 9. The backside contact metallization results in the formation of a backside contact 1010 in the remainder of the backside opening 920 and an additional backside contact 1020 in the additional backside opening. The backside contact 1010 extends to the top S/D epitaxy 622 through the bottom S/D epitaxy 624 with the backside dielectric liner 930 providing electrical isolation of the backside contact 1010 from the bottom S/D epitaxy 624. The additional backside contact 1020 extends to the bottom S/D epitaxy 624. The backside interconnect formation can result in the formation of a BSPDN 1030, for example.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
a back-end-of-line (BEOL) layer;
a backside power distribution network (BSPDN);
a stacked field effect transistor (stacked FET) vertically interposed between the BEOL layer and the BSPDN, the stacked FET comprising a top FET with top source/drain (S/D) epitaxy and a bottom FET with bottom S/D epitaxy and being characterized as having at least partial vertical alignment of the top FET and the bottom FET; and
a backside contact electrically connecting the BSPDN and the top S/D epitaxy and cutting through the bottom S/D epitaxy with isolation between the backside contact and the bottom S/D epitaxy.

2. The semiconductor device according to claim 1, further comprising an additional backside contact electrically connecting the BSPDN and the bottom S/D epitaxy.

3. The semiconductor device according to claim 1, wherein:
the top FET and the bottom FET have a same channel width, and
the semiconductor device further comprises a backside dielectric liner isolating the backside contact from the bottom S/D epitaxy.

4. The semiconductor device according to claim 1, wherein the top FET and the bottom FET have different channel widths.

5. The semiconductor device according to claim 1, wherein the backside contact is disposed in contact with multiple sides of the top S/D epitaxy.

6. The semiconductor device according to claim 1, further comprising a frontside contact electrically connecting the BEOL layer and the bottom S/D epitaxy and cutting through the top S/D epitaxy with isolation between the frontside contact and the top S/D epitaxy.

7. The semiconductor device according to claim 6, further comprising:
an additional backside contact electrically connecting the BSPDN and the bottom S/D epitaxy; and
an additional frontside contact electrically connecting the BEOL layer and the top S/D epitaxy.

8. The semiconductor device according to claim 6, wherein:
the top FET and the bottom FET have a same channel width, and
the semiconductor device further comprises:
a backside dielectric liner isolating the backside contact from the bottom S/D epitaxy; and
a frontside dielectric liner isolating the frontside contact from the top S/D epitaxy.

9. The semiconductor device according to claim 6, wherein at least one of:
the backside contact is disposed in contact with multiple sides of the top S/D epitaxy, and
the frontside contact is disposed in contact with multiple sides of the bottom S/D epitaxy.

10. A semiconductor device, comprising:
a back-end-of-line (BEOL) layer;
a backside power distribution network (BSPDN);
a stacked field effect transistor (stacked FET) vertically interposed between the BEOL layer and the BSPDN, the stacked FET comprising a top FET with top source/drain (S/D) epitaxy and a bottom FET with bottom S/D epitaxy and being characterized as having at least partial vertical alignment of the top FET and the bottom FET and with the top FET and the bottom FET having different channel widths;
a backside contact electrically connecting the BSPDN and the top S/D epitaxy and cutting through the bottom S/D epitaxy with isolation between the backside contact and the bottom S/D epitaxy; and
a frontside contact electrically connecting the BEOL layer and the bottom S/D epitaxy and being displaced from the top S/D epitaxy.

11. The semiconductor device according to claim 10, further comprising:
an additional backside contact electrically connecting the BSPDN and the bottom S/D epitaxy; and
an additional frontside contact electrically connecting the BEOL layer and the top S/D epitaxy.

12. The semiconductor device according to claim 10, further comprising a backside dielectric liner isolating the backside contact from the bottom S/D epitaxy.

13. The semiconductor device according to claim 10, wherein at least one of:
the backside contact is disposed in contact with multiple sides of the top S/D epitaxy, and
the frontside contact is disposed in contact with multiple sides of the bottom S/D epitaxy.

14. A semiconductor device fabrication method, comprising:
forming a stacked field effect transistor (stacked FET) comprising a top FET with top source/drain (S/D) epitaxy and a bottom FET with bottom S/D epitaxy and being characterized as having at least partial vertical alignment of the top FET and the bottom FET;
cutting a frontside opening through the top S/D epitaxy to the bottom S/D epitaxy;
lining the frontside opening with a frontside dielectric liner;
forming, in a frontside opening remainder, a frontside contact cutting through the top S/D epitaxy with frontside dielectric liner isolation to the bottom S/D epitaxy;
cutting a backside opening through the bottom S/D epitaxy to the top S/D epitaxy;
lining the backside opening with a backside dielectric liner; and
forming, in a backside opening remainder, a backside contact cutting through the bottom S/D epitaxy with backside dielectric liner isolation to the top S/D epitaxy.

15. The semiconductor device fabrication method according to claim 14, further comprising:
forming a back-end-of-line (BEOL) layer for electrical connection with the frontside contact; and
forming a backside power distribution network (BSPDN) for electrical connection with the backside contact.

16. The semiconductor device fabrication method according to claim 15, further comprising forming one or more metallization layers between the frontside contact and the BEOL layer.

17. The semiconductor device fabrication method according to claim 14, further comprising:
cutting an additional frontside opening to the top S/D epitaxy forming, in the additional frontside opening, an additional frontside contact to the top S/D epitaxy;
cutting an additional backside opening to the bottom S/D epitaxy; and
forming, in the additional backside opening, an additional backside contact to the bottom S/D epitaxy.

18. The semiconductor device fabrication method according to claim 17, further comprising:
lining the additional backside opening with an additional backside dielectric liner; and
forming the additional backside contact in an additional backside opening remainder.

19. The semiconductor device fabrication method according to claim 18, wherein the backside dielectric liner of the backside contact and the additional backside dielectric liner of the additional backside contact are adjacent.

20. The semiconductor device fabrication method according to claim 14, wherein:
the cutting of the frontside opening and the forming of the frontside contact are executed such that the frontside contact is disposed in contact with multiple sides of the bottom S/D epitaxy, and
the cutting of the backside opening and the forming of the backside contact are executed such that the backside contact is disposed in contact with multiple sides of the top S/D epitaxy.
